(19) United States
(12) Patent Application Publication
(10) Pub. No.: US 2021/0167060 A1
(43) Pub. Date: Jun. 3, 2021

(54) PROTECTION CIRCUIT

(71) Applicant: SONY SEMICONDUCTOR SOLUTIONS CORPORATION, KANAGAWA (JP)

(72) Inventor: SHINICHI MIYAKE, KANAGAWA (JP)

(21) Appl. No.: 16/769,517

(22) PCT Filed: Oct. 24, 2018
(86) PCT No.: PCT/JP2018/039463

§ 371 Date: Jun. 3, 2020

(30) Foreign Application Priority Data
Dec. 14, 2017 (JP) 2017-239416

(51) Int. Cl. H01L 27/02

(52) U.S. Cl. CPC H01L 27/0266; H01L 27/0255

(57) ABSTRACT

To perform protection from damage in a semiconductor device manufacturing process while suppressing an increase in an area. A protection circuit includes at least one protection transistor. A first diffusion layer of the protection transistor is connected to a terminal of a protected circuit. A second diffusion layer of the protection transistor is connected to a ground level. A gate and a well of the protection transistor are connected to power supply lines. When receiving plasma induced damage, voltages of the second diffusion layer, the gate, and the well of the protection transistor are relatively lowered, and the protection transistor operates in a forward bias mode.

### TECHNICAL FIELD

The present technology relates to a protection circuit. More specifically, the present technology relates to a protection circuit that protects a protected circuit from plasma induced damage in a manufacturing process.

### BACKGROUND ART

In a semiconductor device manufacturing process, there is a possibility that a process such as etching, ashing, ion implantation, chemical vapor deposition (CVD), or the like causes plasma induced damage. Therefore, a technology has been proposed that protects a protected circuit to be protected from such damage by connecting to a protection circuit (for example, refer to Patent Document 1).

### CITATION LIST

### Patent Document

### Patent Document 1: Japanese Patent Application Laid-Open No. 2001-057389

### SUMMARY OF THE INVENTION

### Problems to be Solved by the Invention

In the related art, protection from damage is performed by removing charges from a protected circuit in a manufacturing process. However, in the related art, there has been a problem in that it is necessary to provide antenna wiring, an antenna via, an antenna pad, or the like in order to detect the damage and an area for providing the above is required. In particular, in recent years, there is a case where functions of a semiconductor element are expanded by laminating chips. At this time, in a process such as through silicon via (TSV) for connecting between the chips, there is a case where a process damage is large and a large current flows into a transistor during the process. Therefore, in the related art, there has been a problem in that an area of the protection circuit is further increased.

The present technology has been made in view of such a situation, and an object of the present technology is to perform protection from damage of a semiconductor device manufacturing process while suppressing an increase in an area.

### Solutions to Problems

The present technology has been made to solve the above problems. A first aspect of the present technology is a protection circuit including a protection transistor in which a first diffusion layer is connected to a terminal of a protected circuit, a second diffusion layer is connected to a ground level, and a gate and a well are connected to power supply lines. With this protection circuit, an action is obtained for releasing a charge from the second diffusion layer to the ground level when a charge generated by plasma induced damage at a wafer process stage is applied.

Furthermore, in the first aspect, the protection transistor may be a PMOS transistor formed on a buried insulating film. With this structure, in a PMOS transistor having an SOI structure, an action is obtained for releasing a positive charge generated by plasma induced damage from the second diffusion layer to the ground level.

Furthermore, in the first aspect, the protection transistor is a PMOS transistor, and the power supply lines connected to the gate and the well may be different power supply lines. With this structure, in a bulk PMOS transistor, an action is obtained for releasing a positive charge generated by plasma induced damage from the second diffusion layer to the ground level.

Furthermore, in the first aspect, a stabilizing element that is connected to the gate and stabilizes a charge may be further included. With this structure, an action is obtained for further stabilizing an operation as a protection circuit. In this case, the stabilizing element may be a reverse diode.

Furthermore, in the first aspect, a second protection transistor may be further included in which a first diffusion layer is connected to the terminal of the protected circuit and a second diffusion layer, a gate, and a well are connected to the ground level. With this structure, an action is obtained for leaking the positive charge generated by the plasma induced damage by a GIDL and releasing a negative charge generated by the damage caused by the plasma to the ground level by an operation in a forward bias mode. In this case, the second protection transistor may be an NMOS transistor formed on the buried insulating film.

Furthermore, in the first aspect, the well of the protection transistor and the well of the second protection transistor may be connected to different potential control lines. With this structure, an action is obtained for reducing a leakage current at the time of a circuit operation.

### Effects of the Invention

According to the present technology, an excellent effect may be obtained such that protection from damage of a semiconductor device manufacturing process can be performed while suppressing an increase in an area. Note that the effects described herein are not limited and that the effect may be any effects described in the present disclosure.

### BRIEF DESCRIPTION OF DRAWINGS

FIG. 1 is a diagram illustrating an example of a circuit configuration according to a first embodiment of the present technology.

FIG. 2 is a diagram illustrating an example of a behavior when being damaged in the first embodiment of the present technology.

FIG. 3 is a diagram illustrating an example of a behavior in a case where an input signal at the time of a circuit operation is 0 V in the first embodiment of the present technology.

FIG. 4 is a diagram illustrating an example of a behavior in a case where the input signal at the time of the circuit operation is Vdd in the first embodiment of the present technology.

FIG. 5 is a diagram illustrating an example of a circuit configuration according to a second embodiment of the present technology.

FIG. 6 is a diagram illustrating an example of a behavior when being damaged in the second embodiment of the present technology.

FIG. 7 is a diagram illustrating an example of a behavior in a case where an input signal at the time of a circuit operation is 0 V in the second embodiment of the present technology.

FIG. 8 is a diagram illustrating an example of a behavior in a case where the input signal at the time of the circuit operation is Vdd in the second embodiment of the present technology.

FIG. 9 is a diagram illustrating an example of a circuit configuration according to a third embodiment of the present technology.

FIG. 10 is a diagram illustrating an example of a behavior when being damaged by a positive charge in the third embodiment of the present technology.

FIG. 11 is a diagram illustrating an example of a behavior when being damaged by a negative charge in the third embodiment of the present technology.

FIG. 12 is a diagram illustrating an example of a circuit configuration according to a fourth embodiment of the present technology.

FIG. 13 is a diagram illustrating an example of a behavior in a case where a gate and a well are connected to a common power supply line in a bulk transistor.

FIG. 14 is a diagram illustrating an example of a behavior when being damaged in a fifth embodiment of the present technology.

### MODE FOR CARRYING OUT THE INVENTION

Embodiments for carrying out the present technology (referred to as embodiments below) are described below. The description is made in the following order.

1. First Embodiment (example using PMOS transistor as protection circuit)

2. Second Embodiment (example in which reverse diode is added)

3. Third Embodiment (example in which NMOS transistor is added)

4. Fourth Embodiment (example in which back bias is applied)

5. Fifth Embodiment (application example to bulk transistor)

### 1. First Embodiment

[Circuit Configuration]

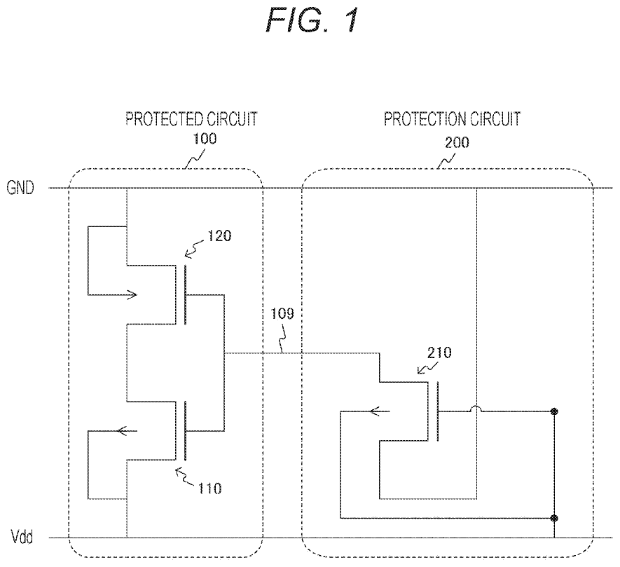

FIG. 1 is a diagram illustrating an example of a circuit configuration according to a first embodiment of the present technology.

In the following embodiment, description will be made as assuming a circuit having a CMOS structure in which a PMOS transistor 110 and an NMOS transistor 120 are connected to each other as a protected circuit 100 to be protected from damage. However, this is merely an example, and the protected circuit 100 is not limited to the circuit having the CMOS structure.

The p-channel metal-oxide semiconductor (PMOS) transistor 110 is a transistor in which a p-channel is formed under a gate oxide film at the time of an operation and a source and a drain are connected. The n-channel metal-oxide semiconductor (NMOS) transistor 120 is a transistor in which an n-channel is formed under a gate oxide film at the time of operation and a source and a drain are connected. The source of the PMOS transistor 110 is connected to a Vdd (power supply level), and the source of the NMOS transistor 120 is connected to a GND (ground level). Furthermore, the drains of the PMOS transistor 110 and the NMOS transistor 120 are connected to each other. Furthermore, the gates of the PMOS transistor 110 and the NMOS transistor 120 are connected to each other. With this structure, a circuit having a complementary metal oxide semiconductor (CMOS) structure in which both transistors complementarily operate is formed.

In the first embodiment, a protection circuit 200 includes a PMOS transistor 210. A source of the PMOS transistor 210 is connected to the gates of the PMOS transistor 110 and the NMOS transistor 120 as a terminal 109 of the protected circuit 100. Furthermore, a drain of the PMOS transistor 210 is connected to the GND. Furthermore, a gate and a well of the PMOS transistor 210 are connected to the Vdd. Note that the PMOS transistor 210 is an example of a protection transistor described in claims.

[Operation]

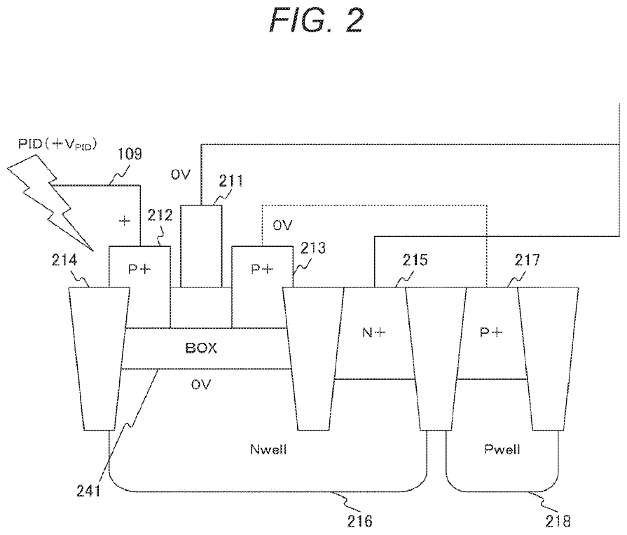

FIG. 2 is a diagram illustrating an example of a behavior when being damaged in the first embodiment of the present technology.

In FIG. 2, a cross-sectional diagram of the PMOS transistor 210 is illustrated. In this example, a silicon on insulator (SOI) structure is assumed. A buried insulating film 241 is formed in an N well 216 formed on a P-type substrate, and the PMOS transistor 210 is formed on the buried insulating film 241. The buried insulating film 241 is a buried oxide film (buried oxide: BOX) used to separate an element from a silicon substrate and is realized by, for example, silicon dioxide (SiO₂), or the like. With this structure, an effect of reducing a capacitance generated between the buried insulating film 241 and the silicon substrate is obtained. An element isolation (shallow trench isolation: STI) 214 separates between the buried insulating film 241 and other element region. Note that the N well 216 is an example of a well of the protection transistor described in claims.

The PMOS transistor 210 is formed on the buried insulating film 241 and includes a gate electrode 211, a source diffusion layer 212, and a drain diffusion layer 213. The gate electrode 211 includes, for example, metal such as polysilicon, and an oxide film is formed below the gate electrode 211. The gate electrode 211 is connected to a power supply line. The diffusion layers 212 and 213 are P-type diffusion layers. The diffusion layer 212 is connected to the terminal 109 of the protected circuit 100. Note that the diffusion layers 212 and 213 are examples of a first and a second diffusion layers of the protection transistor described in claims. Furthermore, the gate electrode 211 is an example of a gate of the protection transistor described in claims.

An N-type region 215 is formed on the N well 216. The N-type region 215 is connected to the power supply line. With this structure, the N well 216 is connected to the power supply line via the N-type region 215.

Furthermore, a P well 218 is formed on the P-type substrate in addition to the N well 216. The P well 218 becomes the GND. That is, a charge of the P well 218 flows to the P-type substrate. A P-type region 217 is formed on the P well 218. The P-type region 217 is connected to the diffusion layer 213. With this structure, the diffusion layer 213 is connected to the GND via the P-type region 217.

It is assumed that a positive charge VPID is generated in the terminal 109 as a result of receiving plasma induced damage (plasma induced damage: PID) at a wafer process stage. The positive charge is assumed because there are many cases where the positive charge is received as the PID in the process. The positive charge is applied to the source diffusion layer 212 of the PMOS transistor 210. At this time, the positive charge is not applied to the drain diffusion layer 213, the gate electrode 211, and the N well 216 of the PMOS transistor 210.

As a result, voltages of the drain diffusion layer 213, the gate electrode 211, and the N well 216 of the PMOS transistor 210 are relatively lowered. With this voltage drop, the PMOS transistor 210 operates in a forward bias mode (forward body bias: FBB) and is turned on. At this time, in order to stably lower a potential of the drain than the source, the drain diffusion layer 213 is connected to the GND (P-type region 217/P well 218). With this structure, the positive charge is released from the drain diffusion layer 213 to the P well 218 via the P-type region 217.

In the wafer process stage, the gate electrode 211 and the N well 216 of the PMOS transistor 210 are in a floating state. If the charges are not accumulated in the gate electrode 211 and the N well 216, it is considered that a degree of a fluctuation in a potential is small. When the positive charge caused by the PID is larger than the fluctuation, the PMOS transistor 210 operates.

In a case where a semiconductor device is completely manufactured and an actual operation environment is achieved, the protection circuit 200 does not affect a normal circuit operation. An operation in that case will be described below.

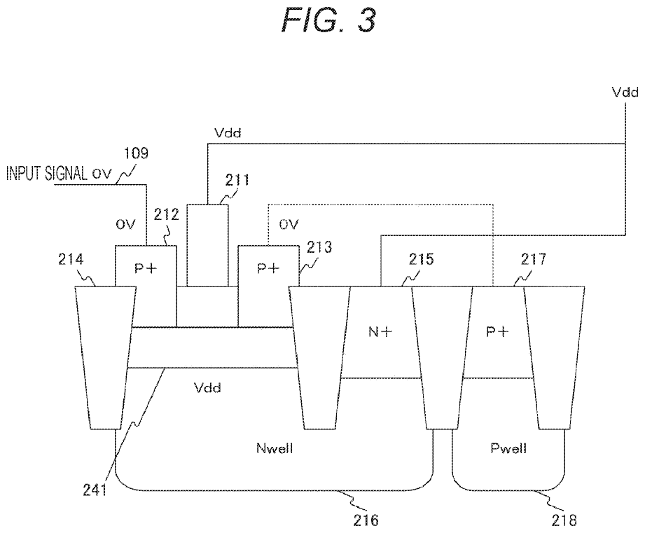

FIG. 3 is a diagram illustrating an example of a behavior in a case where an input signal at the time of a circuit operation is 0 V in the first embodiment of the present technology.

At the time of the circuit operation, the gate electrode 211 and the N well 216 of the PMOS transistor 210 are connected to the Vdd. The diffusion layer 212 is connected to the terminal 109 of the protected circuit 100. The diffusion layer 213 is connected to the GND.

In a case where an input signal of the terminal 109 of the protected circuit 100 is “0” (0 V), there is no potential difference between the diffusion layers 212 and 213. Therefore, the PMOS transistor 210 does not operate.

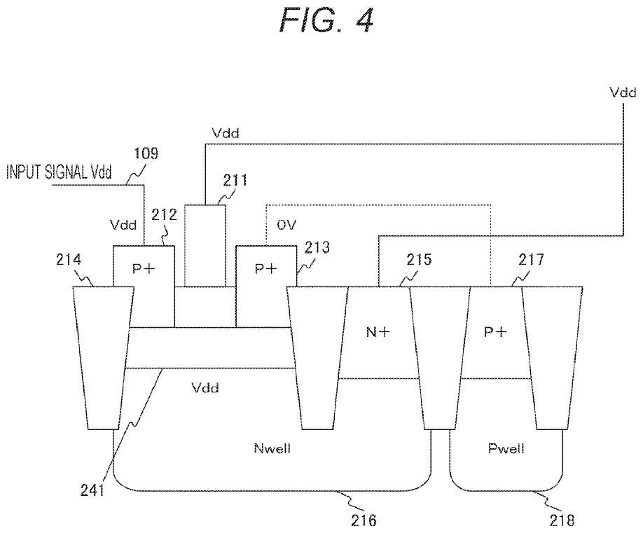

FIG. 4 is a diagram illustrating an example of a behavior in a case where the input signal at the time of the circuit operation is Vdd in the first embodiment of the present technology.

In a case where the input signal of the terminal 109 of the protected circuit 100 shifts from “0” to “1” (Vdd), although a positive potential is applied to the diffusion layer 212, only an off current flows.

Therefore, it is found that the protection circuit 200 does not operate regardless of the input signal of the terminal 109.

In this way, according to the first embodiment of the present technology, when the plasma induced damage is received at the wafer process stage, the PMOS transistor 210 operates in the forward bias mode, and the charge of the protected circuit 100 can be extracted. On the other hand, at the time of the circuit operation after manufacturing, the PMOS transistor 210 does not operate and does not affect the normal circuit operation.

### 2. Second Embodiment

[Circuit Configuration]

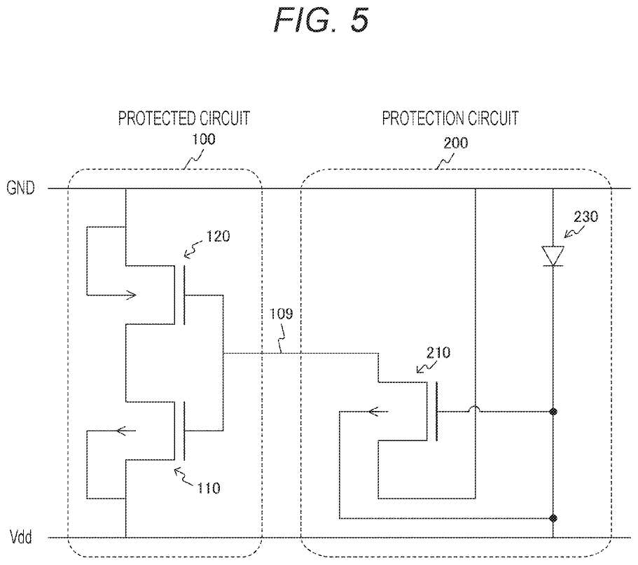

FIG. 5 is a diagram illustrating an example of a circuit configuration according to a second embodiment of the present technology.

The second embodiment is different from the first embodiment in that a reverse diode 230 is further provided as the protection circuit 200, and other points are similar to those of the first embodiment. The reverse diode 230 stabilizes an operation as the protection circuit 200 by fixing potentials of a gate and a well of a PMOS transistor 210.

[Operation]

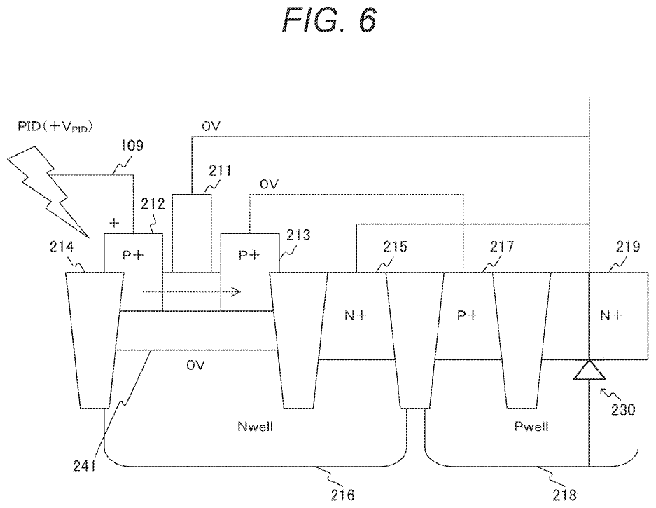

FIG. 6 is a diagram illustrating an example of a behavior when being damaged in the second embodiment of the present technology.

In the second embodiment, an N-type region 219 is formed on a P well 218. By connecting the P well 218 and the N-type region 219, the reverse diode 230 is formed. The N-type region 219 is connected to a power supply line. With this connection, the N-type region 219 is connected to a gate electrode 211 and an N-type region 215. Therefore, potentials of the gate electrode 211 and the N well 216 that are in the floating state in the first embodiment are fixed, and operations are stabilized.

An operation at the time of receiving plasma induced damage at a wafer process stage is similar to that in the first embodiment. Voltages of a drain diffusion layer 213, the gate electrode 211, and the N well 216 of the PMOS transistor 210 are relatively lowered by applied positive charges so that the PMOS transistor 210 operates in a forward bias mode. At this time, in order to stably lower a potential than that of the source, the drain diffusion layer 213 is connected to a GND (P-type region 217 and P well 218). In addition, the gate electrode 211 and the N well 216 are connected to the reverse diode 230. With this structure, the positive charge is released from the drain diffusion layer 213 to the P well 218 via the P-type region 217.

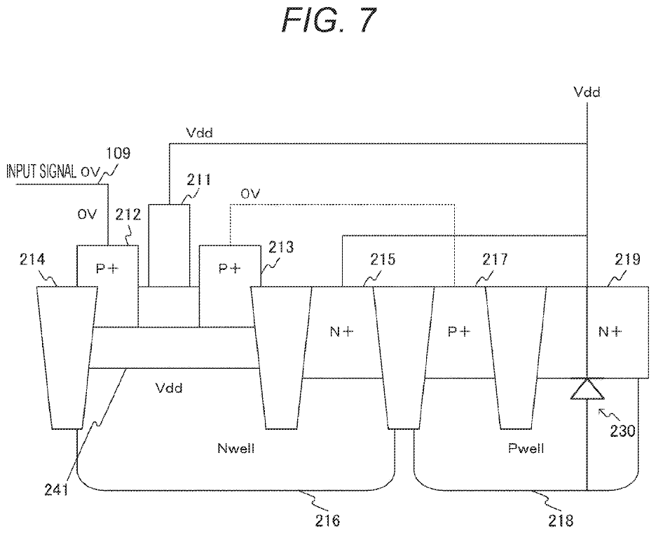

FIG. 7 is a diagram illustrating an example of a behavior in a case where an input signal at the time of a circuit operation is 0 V in the second embodiment of the present technology.

At the time of the circuit operation, as in the first embodiment, the gate electrode 211 and the N well 216 of the PMOS transistor 210 are connected to a Vdd. The diffusion layer 212 is connected to the terminal 109 of the protected circuit 100. The diffusion layer 213 is connected to the GND.

In a case where an input signal of the terminal 109 of the protected circuit 100 is “0” (0 V), there is no potential difference between the diffusion layers 212 and 213. Therefore, as in the first embodiment, the PMOS transistor 210 does not operate.

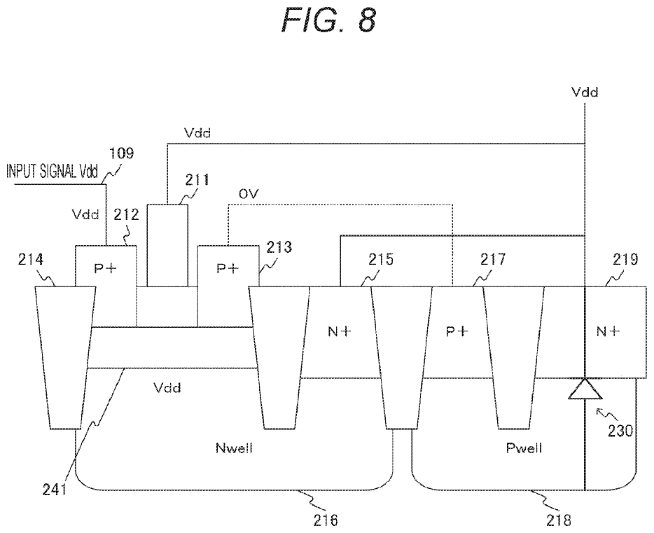

FIG. 8 is a diagram illustrating an example of a behavior in a case where the input signal at the time of the circuit operation is Vdd in the second embodiment of the present technology.

As in the first embodiment, in a case where the input signal of the terminal 109 of the protected circuit 100 shifts from “0” to “1” (Vdd), although a positive potential is applied to the diffusion layer 212, only an off current flows.

Therefore, it is found that the protection circuit 200 does not operate regardless of the input signal of the terminal 109.

In this way, according to the second embodiment of the present technology, by connecting the gate electrode 211 and the N well 216 to the reverse diode 230, the potentials of the gate electrode 211 and the N well 216 are fixed, and the operation as the protection circuit 200 can be stabilized.

### 3. Third Embodiment

[Circuit Configuration]

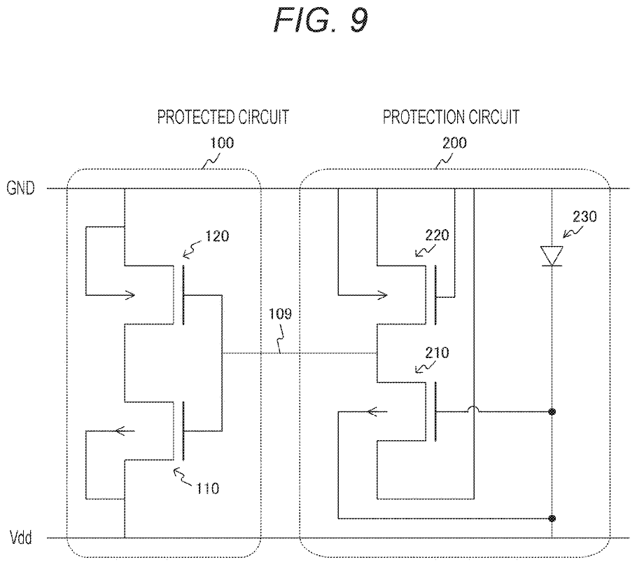

FIG. 9 is a diagram illustrating an example of a circuit configuration according to a third embodiment of the present technology.

The third embodiment is different from the second embodiment in that an NMOS transistor 220 is further provided as a protection circuit 200, and other points are similar to those of the second embodiment. Note that a configuration in which a reverse diode 230 is not provided as in the first embodiment may be used.

In the NMOS transistor 220, one of a source or a drain is connected to a terminal 109 of a protected circuit 100, and the other one of the source or the drain, a gate, and a well are connected to a GND.

In this case, when a positive charge is received as plasma induced damage at a wafer process stage, in addition to the above embodiments, protection by a gate-induced drain leakage current (GIDL) of the NMOS transistor 220 can be achieved. The GIDL is a leakage current caused by a tunnel phenomenon between bands in an overlap region of the gate and the drain. However, an amount of the leakage current caused by the GIDL is not large, and an operation by the forward bias mode of the PMOS transistor 210 is dominant.

On the other hand, when a negative charge is received as the plasma induced damage, the NMOS transistor 220 can operate in the forward bias mode so as to release a charge. At this time, although the PMOS transistor 210 causes the leakage current by the GIDL to flow, the operation by the forward bias mode of the NMOS transistor 220 is dominant.

[Operation]

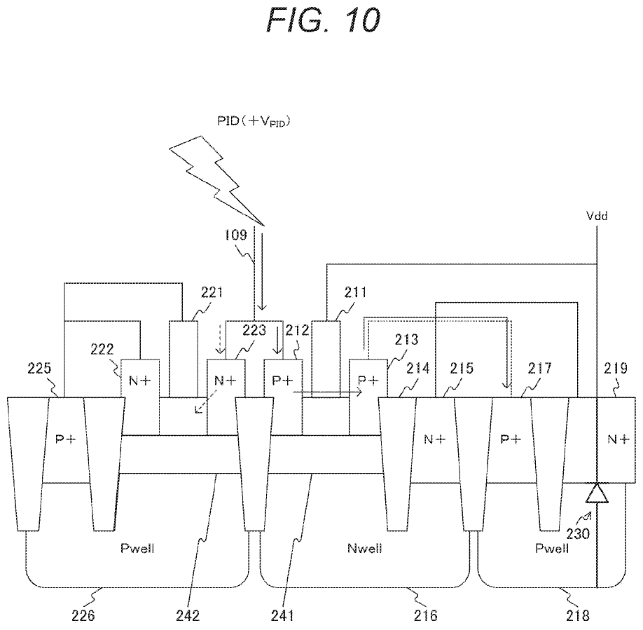

FIG. 10 is a diagram illustrating an example of a behavior when being damaged by a positive charge in the third embodiment of the present technology.

In the third embodiment, a P well 226 is formed below a buried insulating film 242. The P well 226 becomes the GND. That is, a charge of the P well 226 flows to the P-type substrate. A P-type region 225 is formed on the P well 226. Note that the P well 226 is an example of a well of a second protection transistor described in claims.

The NMOS transistor 220 is formed on the buried insulating film 242 and includes a gate electrode 221 and diffusion layers 222 and 223. The gate electrode 221 and the diffusion layer 222 are connected to the P-type region 225. With this structure, the gate electrode 221 and the diffusion layer 222 are connected to the GND via the P-type region 225. The diffusion layer 223 is connected to a terminal 109 of a protected circuit 100. Note that the diffusion layers 223 and 222 are examples of a first and a second diffusion layers of the second protection transistor described in claims. Furthermore, the gate electrode 221 is an example of a gate of the second protection transistor described in claims.

When a positive charge is generated as the plasma induced damage, the positive charge is applied to the source diffusion layer 212 of the PMOS transistor 210 and the drain diffusion layer 223 of the NMOS transistor 220.

As a result, voltages of the drain diffusion layer 213, the gate electrode 211, and the N well 216 of the PMOS transistor 210 are relatively lowered. As a result, the PMOS transistor 210 operates in the forward bias mode and is turned on. With this structure, the positive charge is released from the drain diffusion layer 213 to the P well 218 via the P-type region 217.

On the other hand, the NMOS transistor 220 leaks the positive charge of the drain diffusion layer 223 by the GIDL. The positive charge by the GIDL is released from the source diffusion layer 222 to the P well 226 via the P-type region 225.

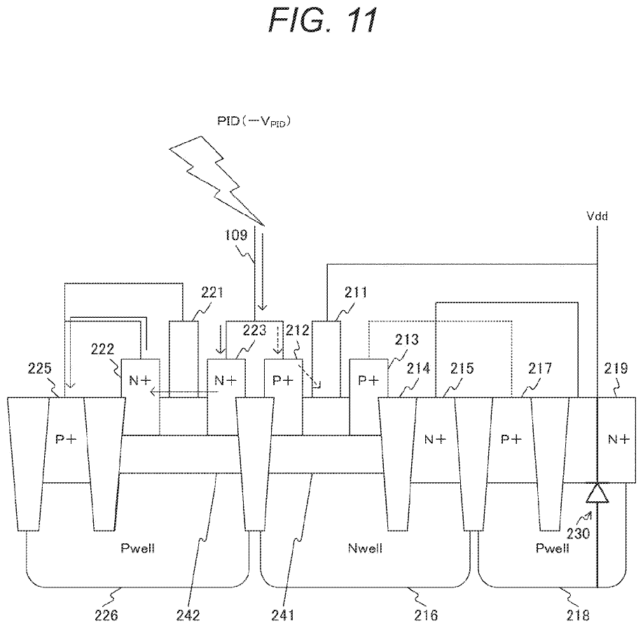

FIG. 11 is a diagram illustrating an example of a behavior when being damaged by a negative charge in the third embodiment of the present technology.

When a negative charge is generated as the plasma induced damage, the negative charge is applied to the drain diffusion layer 212 of the PMOS transistor 210 and the source diffusion layer 223 of the NMOS transistor 220.

As a result, voltages of the source diffusion layer 223, the gate electrode 221, and the P well 226 of the NMOS transistor 220 are relatively lowered. As a result, the NMOS transistor 220 operates in the forward bias mode and is turned on. With this operation, the negative charge is released from the source diffusion layer 223 to the P well 226 via the P-type region 225.

On the other hand, the PMOS transistor 210 leaks the negative charge of the drain diffusion layer 212 by the GIDL. The negative charge by the GIDL is released from the source diffusion layer 213 to the P well 218 via the P-type region 217.

As described above, according to the third embodiment of the present technology, by providing the NMOS transistor 220, the charge of the protected circuit 100 can be extracted by the GIDL when the positive charge is generated as the plasma induced damage. Furthermore, the NMOS transistor 220 can operate in the forward bias mode and extract the charge of the protected circuit 100 when the negative charge is generated as the plasma induced damage.

### 4. Fourth Embodiment

[Circuit Configuration]

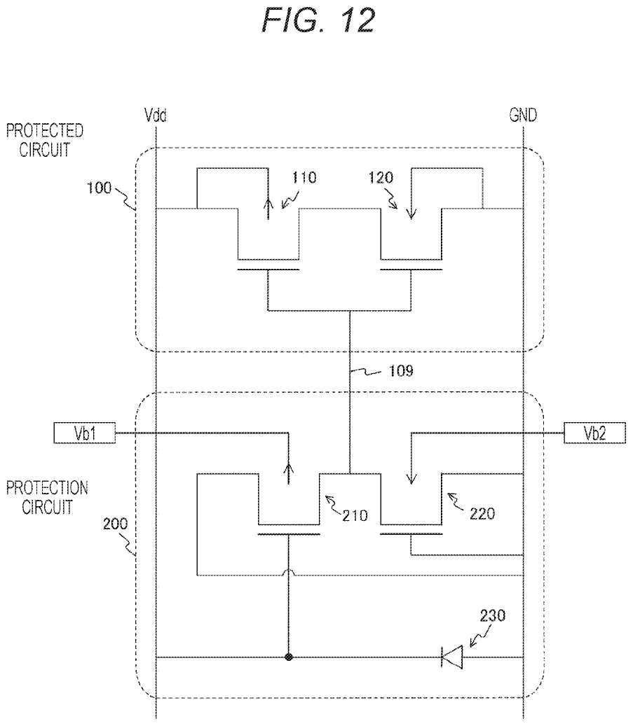

FIG. 12 is a diagram illustrating an example of a circuit configuration according to a fourth embodiment of the present technology.

In the fourth embodiment, by providing a circuit that adjusts a potential in each of wells of a PMOS transistor 210 and an NMOS transistor 220 of a protection circuit 200, an off current at the time of the circuit operation is reduced. That is, by applying reverse back bias (RBB) to the PMOS transistor 210 and the NMOS transistor 220, it is possible to reduce an off-leak current.

In this example, a positive potential Vb1 is applied to the well of the PMOS transistor 210. On the other hand, a negative potential Vb2 is applied to the well of the NMOS transistor 220. With this application, threshold voltages of the PMOS transistor 210 and the NMOS transistor 220 are increased, and it is possible to reduce a leakage current at the time of the circuit operation.

In this way, according to the fourth embodiment of the present technology, by providing the circuit that adjusts the potential in the well of each of the PMOS transistor 210 and the NMOS transistor 220, it is possible to reduce the leakage current at the time of the circuit operation.

### 5. Fifth Embodiment

In the first to the fourth embodiments, the SOI structure is assumed, and common power is supplied to the gate and the well of the PMOS transistor 210. On the other hand, the present technology can be applied to a bulk transistor that does not employ the SOI structure. In this case, when the gate and the well of the PMOS transistor 210 are connected to a common power supply line as in the first to the fourth embodiments, a current from the well generated by the plasma induced damage is applied to the gate, and the PMOS transistor 210 does not operate as a protection circuit. The following figure illustrates this situation.

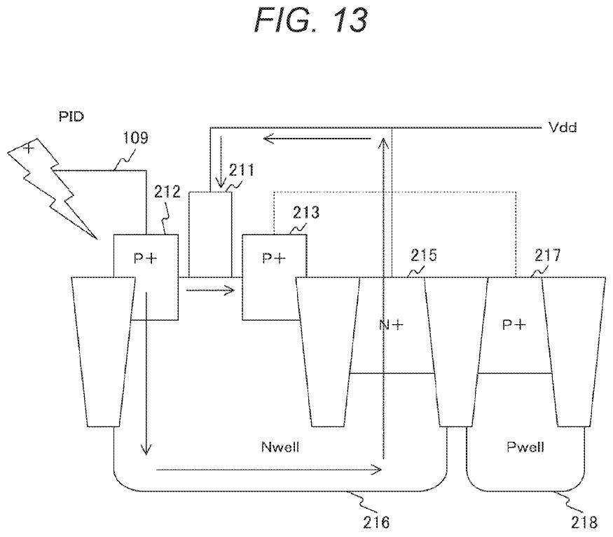

FIG. 13 is a diagram illustrating an example of a behavior in a case where a gate and a well are connected to a common power supply line in a bulk transistor.

When a positive charge is applied to a diffusion layer 212 as the plasma induced damage, the positive charge flows to an N well 216. In this case, since the N-type region 215 is connected to a gate electrode 211 via the common power supply line, a current flows from the N well 216 into the gate electrode 211. Therefore, when receiving the plasma induced damage, a situation occurs where the transistor does not operate as a protection circuit.

Therefore, in the fifth embodiment, a bulk transistor is assumed, and a power supply line of the gate electrode 211 and a power supply line of the N-type region 215 are separately provided as illustrated in the following figure.

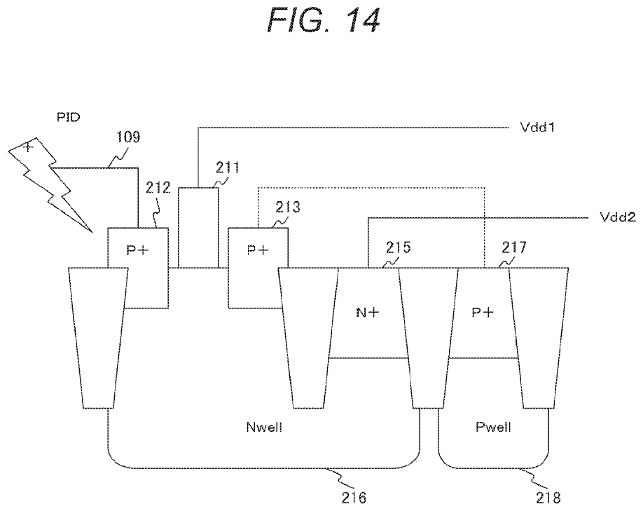

FIG. 14 is a diagram illustrating an example of a behavior when being damaged in the fifth embodiment of the present technology.

In this example, unlike the first to the fourth embodiments, the gate electrode 211 is connected to a power supply line Vdd1, and the N-type region 215 is connected to a power supply line Vdd2. That is, the gate electrode 211 and the N-type region 215 are respectively connected to different power supply lines. With this structure, it is possible to prevent a current from flowing from the N well 216 to the gate electrode 211, and the present technology can be applied to the bulk transistor.

Note that the fifth embodiment can be similarly applied to the second and the third embodiments. That is, an N-type region 219 may be provided on a P well 218 to form a reverse diode 230. Furthermore, an NMOS transistor 220 may be provided. Furthermore, a circuit that adjusts a potential may be provided in a well of each of the PMOS transistor 210 and the NMOS transistor 220.

In this way, according to the fifth embodiment of the present technology, by separately connecting the gate electrode 211 and the N-type region 215 to the different power supply lines, even when the PMOS transistor 210 is a bulk transistor, the PMOS transistor 210 can properly operate as a protection circuit.

Note that the embodiments indicate examples for embodying the present technology, and matters in the embodiments and invention specifying matters in claims have correspondence relations. Similarly, the invention specifying matters in claims and the matters in the embodiments of the present technology denoted by the same names have correspondence relations. However, the present technology is not limited to the embodiments, and can be embodied by applying various modifications to the embodiments without departing from the scope of the present technology.

Note that the effects described herein are only exemplary and not limited to these. In addition, there may be an additional effect.

Note that, the present technology can have the following configuration.

(1) A protection circuit including: a protection transistor in which a first diffusion layer is connected to a terminal of a protected circuit, a second diffusion layer is connected to a ground level, and a gate and a well are connected to power supply lines.

(2) The protection circuit according to (1), in which

the protection transistor is a PMOS transistor formed on a buried insulating film.

(3) The protection circuit according to (1), in which

the protection transistor is a PMOS transistor, and the power supply lines connected to the gate and the well are different from each other.

(4) The protection circuit according to any one of (1) to (3), further including: a stabilizing element configured to be connected to the gate and stabilize a charge.

(5) The protection circuit according to (4), in which the stabilizing element is a reverse diode.

(6) The protection circuit according to any one of (1) to (5), further including:

a second protection transistor in which a first diffusion layer is connected to the terminal of the protected circuit and a second diffusion layer, a gate, and a well are connected to the ground level.

(7) The protection circuit according to (6), in which

the second protection transistor is an NMOS transistor formed on the buried insulating film.

(8) The protection circuit according to (6), in which

the well of the protection transistor and the well of the second protection transistor are connected to different potential control lines.

### REFERENCE SIGNS LIST

100 Protected circuit
109 Terminal
110 PMOS transistor
120 NMOS transistor
200 Protection circuit
210 PMOS transistor
211 Gate electrode
212, 213 Diffusion layer
214 Element isolation (shallow trench isolation: STI)
241 Buried insulating film (buried oxide: BOX)
215 N-type region
216 N well
217 P-type region
218 P well
219 N-type region
220 NMOS transistor
221 Gate electrode
222, 223 Diffusion layer
225 P-type region
226 P well
230 Reverse diode

1. A protection circuit comprising: a protection transistor in which a first diffusion layer is connected to a terminal of a protected circuit, a second diffusion layer is connected to a ground level, and a gate and a well are connected to power supply lines.

2. The protection circuit according to claim 1, wherein
the protection transistor is a PMOS transistor formed on a buried insulating film.

3. The protection circuit according to claim 1, wherein
the protection transistor is a PMOS transistor, and the power supply lines connected to the gate and the well are different from each other.

4. The protection circuit according to claim 1, further comprising: a stabilizing element configured to be connected to the gate and stabilize a charge.

5. The protection circuit according to claim 4, wherein
the stabilizing element is a reverse diode.

6. The protection circuit according to claim 1, further comprising:
a second protection transistor in which a first diffusion layer is connected to the terminal of the protected circuit and a second diffusion layer, a gate, and a well are connected to the ground level.

7. The protection circuit according to claim 6, wherein
the second protection transistor is an NMOS transistor formed on the buried insulating film.

8. The protection circuit according to claim 6, wherein
the well of the protection transistor and the well of the second protection transistor are connected to different potential control lines.
